(19) United States
(12) Patent Application Publication
(10) Pub. No.: US 2024/0347587 A1
(43) Pub. Date: Oct. 17, 2024

(54) SUPERJUNCTION SILICON CARBIDE SEMICONDUCTOR DEVICE AND METHOD OF MANUFACTURING SUPERJUNCTION SILICON CARBIDE SEMICONDUCTOR DEVICE

(71) Applicant: FUJI ELECTRIC CO., LTD., Kawasaki-shi (JP)

(72) Inventors: Kensuke TAKENAKA, Tsukuba-city (JP); Takeshi TAWARA, Tsukuba-city (JP); Shinsuke HARADA, Tsukuba-city (JP)

(73) Assignee: FUJI ELECTRIC CO., LTD., Kawasaki-shi (JP)

(21) Appl. No.: 18/626,461

(22) Filed: Apr. 4, 2024

(30) Foreign Application Priority Data
Apr. 17, 2023 (JP) 2023-067498

(51) Int. Cl. H01L 29/06; H01L 29/16; H01L 29/66

(52) U.S. Cl. CPC H01L 29/0634; H01L 29/1608; H01L 29/66068

(57) ABSTRACT

A superjunction silicon carbide semiconductor device has a silicon carbide semiconductor substrate, a first semiconductor layer of the first conductivity type, a parallel pn region with first column regions of the first conductivity type and second column regions of a second conductivity type disposed therein repeatedly alternating with one another, a second semiconductor layer of the first conductivity type, a third semiconductor layer of the second conductivity type, a first semiconductor region of the first conductivity type, trenches, a second semiconductor region of the second conductivity type, a third semiconductor region of the second conductivity type, gate electrodes, and an electrode. The first column regions and the second column regions contain phosphorus as a dopant.

### CROSS REFERENCE TO RELATED APPLICATIONS

This application is based upon and claims the benefit of priority of the prior Japanese Patent Application No. 2023-067498, filed on Apr. 17, 2023, the entire contents of which are incorporated herein by reference.

### BACKGROUND OF THE INVENTION

### 1. Field of the Invention

Embodiments of the invention relate to a superjunction silicon carbide semiconductor device and a method of manufacturing a superjunction silicon carbide semiconductor device.

### 2. Description of the Related Art

In a conventional silicon carbide metal-oxide-semiconductor field effect transistor (MOSFET), a high-quality interface between silicon carbide and a gate oxide film is created and resistance is lowered by combining epitaxial growth and ion implantation. Further, a highly reliable high-voltage semiconductor device is realized by having a structure such that high electric field is not applied to the gate oxide film (for example, refer to International Publication No. WO 2017/064949).

For example, to realize reductions in resistance, a high-quality interface is created between the gate oxide film and silicon carbide and a doping concentration of a junction field effect transistor (JFET) portion is increased. Further, a p-type region for mitigating electric field beneath a gate electrode is formed, thereby realizing high voltage capability and high reliability. Further, a deep p-type region is formed beneath a contact region, thereby eliminating flow of an avalanche current near the gate electrode and reducing load on the gate electrode, the avalanche current being generated when high voltage at least equal to a performance limit is applied to a drain electrode. Further, due to the deep p-type region beneath the contact region, even when the built-in diode operates, the flow of a large current near the gate electrode is eliminated and thus, the load on the gate electrode is reduced and reliability is enhanced.

Here, in a normal n-type channel vertical MOSFET, an n-type conduction layer (drift layer) is the semiconductor layer having the highest resistance among multiple semiconductor layers formed in a semiconductor substrate. Electrical resistance of the n-type drift layer greatly affects on-resistance of the vertical MOSFET overall. Overall reduction of the on-resistance of the vertical MOSFET may be realized by reducing a thickness of the n-type drift layer and shortening the current path.

Nonetheless, the vertical MOSFET has a function of sustaining breakdown voltage by the spreading of a depletion layer to the high-resistance n-type drift layer, during an off-state. Thus, when the thickness of the n-type drift layer is decreased to reduce the on-resistance, the spreading of the depletion layer in the off-state is shortened and thus, critical electric field strength is easily reached by application of a low voltage and the breakdown voltage decreases. On the other hand, increasing the thickness of the n-type drift layer is necessary to increase the breakdown voltage of the vertical MOSFET, whereby the on-resistance increases. A relationship such as that between the on-resistance and the breakdown voltage is called a tradeoff relationship and improving both counterparts having a tradeoff relationship is generally difficult. The tradeoff relationship between the on-resistance and the breakdown voltage is known to similarly occur in other semiconductor devices as well, such as insulated gate bipolar transistors (IGBTs), bipolar transistors, diodes, and the like.

A superjunction (SJ) structure is known as a structure of a semiconductor device solving problems such as those described above (for example, refer to International Publication No. WO 2013/0179820 and Japanese Laid-Open Patent Publication No. 2009-130106). FIG. 14 is a cross-sectional view depicting a structure of a conventional superjunction silicon carbide semiconductor device.

FIG. 14 depicts, as a superjunction silicon carbide semiconductor device, a MOSFET (hereinafter, SJ-MOSFET) having a superjunction structure. As depicted in FIG. 14, a SJ-MOSFET 150 has, as a material, a wafer in which an n-type buffer layer 117 and an n-type drift layer 102 are grown on an n⁺-type silicon carbide semiconductor substrate 101 having a high doping concentration. p-type column regions 103 penetrating through the n-type drift layer 102 from a surface of the wafer and not reaching the n⁺-type silicon carbide semiconductor substrate 101 are provided. In FIG. 14, while the p-type column regions 103 do not reach the n⁺-type silicon carbide semiconductor substrate 101, the p-type column regions 103 may reach the n⁺-type silicon carbide semiconductor substrate 101.

Further, the n-type drift layer 102 has a parallel structure (hereinafter, parallel pn structure 121, or parallel pn region) in which p-type regions (the p-type column regions 103) extending in a direction orthogonal to a main surface of the substrate and having a narrow width in a plane parallel to the main surface of the substrate are disposed repeatedly alternating with n-type regions (portions of the n-type drift layer 102 intervening between the p-type column regions 103; hereinafter, n-type column regions 104) in a plane parallel to the main surface of the substrate. The p-type column regions 103 and the n-type column regions 104 configuring the parallel pn structure 121 are regions with an increased doping concentration relative to that of the n-type drift layer 102. In the parallel pn structure 121, the amount of dopant in the p-type column regions 103 is a product obtained by multiplying the area of the p-type column regions 103 by the amount of dopant in the p-type column regions 103 while the amount of dopant in the n-type column regions 104 is a product obtained by multiplying the area of the n-type column regions 104 by the amount of dopant in the n-type column regions 104, and the amount of dopant in the p-type column regions 103 and the amount of dopant in the n-type column regions 104 are charge balanced, whereby in the off-state, a pseudo non-doped layer is created and the breakdown voltage may be increased.

In FIG. 14, reference numerals 105, 106, 107, 108, 109, 110, 111, 112, 114, 115, and 116 are, respectively, an n-type high-concentration region, a p-type base layer, n⁺-type source regions, p⁺-type contact regions, a gate insulating film, a gate electrode, an interlayer insulating film, a source electrode, first p⁺-type base regions, second p⁺-type base regions, and trenches.

Further, among a superjunction semiconductor devices having a parallel pn layer in which first-conductivity-type drift regions and second-conductivity-type partitioning regions are alternately disposed, a superjunction semiconductor device in which a dopant of the first-conductivity-type regions is phosphorus is described (for example, refer to Japanese Laid-Open Patent Publication No. 2006-100862).

### SUMMARY OF THE INVENTION

According to an embodiment of the present invention, a superjunction silicon carbide semiconductor device includes: a silicon carbide semiconductor substrate of a first conductivity type, the silicon carbide semiconductor substrate having a main surface; a first semiconductor layer of the first conductivity type, provided at the main surface of the silicon carbide semiconductor substrate, the first semiconductor layer having a first surface and a second surface opposite to each other, the second surface of first semiconductor layer facing the silicon carbide semiconductor substrate; a parallel pn region provided at the first surface of the first semiconductor layer, the parallel pn region having a first surface and a second surface opposite to each other, the second surface of the parallel pn region facing the silicon carbide semiconductor substrate, the parallel pn region having therein a plurality of first column regions of the first conductivity type and a plurality of second column regions of a second conductivity type disposed repeatedly alternating with one another in a direction parallel to the main surface; a second semiconductor layer of the first conductivity type, provided at the first surface of the parallel pn region, the second semiconductor layer having a first surface and a second surface opposite to each other, the second surface of the second semiconductor layer facing the silicon carbide semiconductor substrate; a third semiconductor layer of the second conductivity type, provided at the first surface of the second semiconductor layer; a first semiconductor region of the first conductivity type, selectively provided in the third semiconductor layer and having a doping concentration higher than a doping concentration of the first semiconductor layer; a trench penetrating through the first semiconductor region and the third semiconductor layer and reaching the second semiconductor layer; a second semiconductor region of the second conductivity type, provided in the second semiconductor layer and in contact with a bottom of the trench; a third semiconductor region of the second conductivity type, provided in the second semiconductor layer, at the first surface of the second semiconductor layer, apart from the trench; a gate insulating film provided in the trench; a gate electrode provided on the gate insulating film, in the trench; and an electrode in contact with the first semiconductor region and the third semiconductor layer. The plurality of first column regions and the plurality of second column regions contain phosphorus as a dopant thereof.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of a superjunction silicon carbide semiconductor device according to a first embodiment.

FIG. 2 is a cross-sectional view depicting a state of the superjunction silicon carbide semiconductor device according to the first embodiment during manufacture.

FIG. 3 is a cross-sectional view depicting a state of the superjunction silicon carbide semiconductor device according to the first embodiment during manufacture.

FIG. 4 is a cross-sectional view depicting a state of the superjunction silicon carbide semiconductor device according to the first embodiment during manufacture.

FIG. 5 is a cross-sectional view depicting a state of the superjunction silicon carbide semiconductor device according to the first embodiment during manufacture.

FIG. 6 is a cross-sectional view depicting a state of the superjunction silicon carbide semiconductor device according to the first embodiment during manufacture.

FIG. 7 is a cross-sectional view depicting a state of the superjunction silicon carbide semiconductor device according to the first embodiment during manufacture.

FIG. 8 is a cross-sectional view depicting a state of the superjunction silicon carbide semiconductor device according to the first embodiment during manufacture.

FIG. 9 is a cross-sectional view depicting a state of the superjunction silicon carbide semiconductor device according to the first embodiment during manufacture.

FIG. 10 is a graph showing concentrations of P and Al in regions implanted with P ions and Al ions in a method of manufacturing the superjunction silicon carbide semiconductor device according to the first embodiment.

FIG. 11 is a graph showing results of simulation of the average range with respect to acceleration energies of N ions, Al ions, and P ions implanted in SiC.

FIG. 12 is a cross-sectional view depicting a structure of a superjunction silicon carbide semiconductor device according to a second embodiment.

FIG. 13 shows results of simulation of profiles of dopant concentrations of a parallel pn structure 21′ depicted in FIG. 12.

FIG. 14 is a cross-sectional view depicting a structure of a conventional superjunction silicon carbide semiconductor device.

FIG. 15 is a cross-sectional view depicting a state during manufacture of the conventional superjunction silicon carbide semiconductor device.

FIG. 16 is a cross-sectional view depicting a state during manufacture of the conventional superjunction silicon carbide semiconductor device.

FIG. 17 is a cross-sectional view depicting a state during manufacture of the conventional superjunction silicon carbide semiconductor device.

FIG. 18 is a cross-sectional view depicting a state during manufacture of the conventional superjunction silicon carbide semiconductor device.

### DETAILED DESCRIPTION OF THE INVENTION

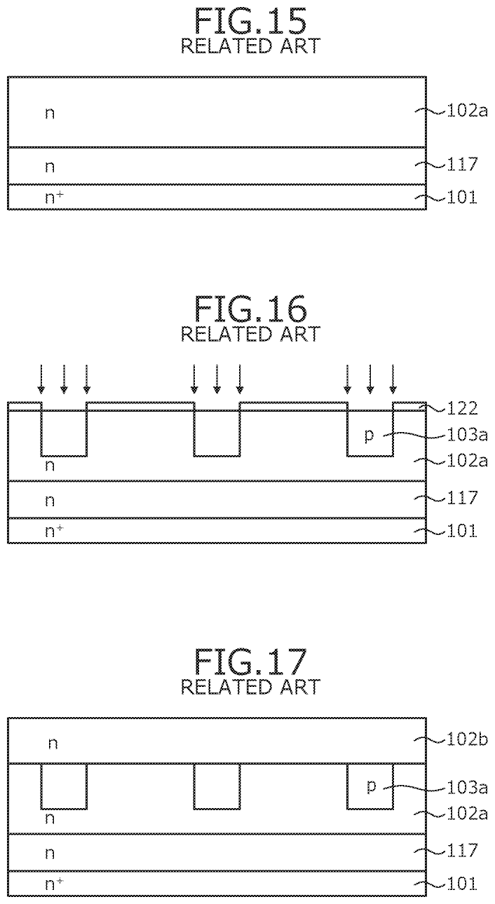

First, problems associated with the conventional techniques are discussed. In a method of manufacturing a superjunction silicon carbide semiconductor device, silicon carbide (SiC) has almost no diffusion of dopant elements and thus, the parallel pn structure 121 is formed by a combination of epitaxial growth and ion implantation. For example, the SJ-MOSFET 150 is manufactured as follows. FIGS. 15, 16, 17, and 18 are cross-sectional views depicting states during manufacture of the conventional superjunction silicon carbide semiconductor device.

First, an n⁺-type silicon carbide substrate 101 containing single-crystal 4H-SiC (four-layer periodic hexagonal crystalline silicon carbide) of an n-type is prepared. Subsequently, on a first main surface of the n⁺-type silicon carbide substrate 101, the n-type buffer layer 117 and a first n-type drift layer 102a are grown by epitaxy. The state up to here is depicted in FIG. 15.

Next, on the surface of the first n-type drift layer 102a, an ion implantation mask 122 having predetermined openings is formed by photolithography, using, for example, a SiO₂ film (hereinafter, oxide film). Subsequently, aluminum ions (hereinafter, Al ions) are implanted in the openings of the oxide film, thereby forming first p-type column regions 103a. The state up to here is depicted in FIG. 16.

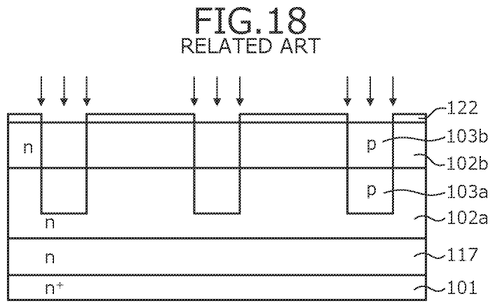

Next, at a front side of the first n-type drift layer 102a, a second n-type drift layer 102b containing silicon carbide is grown by epitaxy while nitrogen atoms are doped. The state up to here is depicted in FIG. 17.

Next, on the surface of the second n-type drift layer 102b, the ion implantation mask 122 having predetermined openings is formed by photolithography, using an oxide film. Subsequently, Al ions are implanted in the openings of the oxide film, thereby forming second p-type column regions 103b. The state up to here is depicted in FIG. 18.

Next, a process including the epitaxial growth depicted in FIG. 17 and the ion implantation depicted in FIG. 18 is repeated a predetermined number of times, thereby forming the p-type column regions 103 and the n-type column regions 104. Thereafter, the n-type high-concentration region 105 is formed by epitaxial growth, and the first p⁺-type base regions 114 and the second p⁺-type base regions 115 are formed by ion implantation. The first p-type column regions 103a and the second p-type column regions 103b are portions of the p-type column regions 103, and the first n-type drift layer 102a and the second n-type drift layer 102b are portions of the n-type column regions 104.

Next, on the surface of the n-type high-concentration region 105, the p-type base layer 106 doped with a p-type dopant such as aluminum is formed. Next, on the surface of the p-type base layer 106, the n⁺-type source regions 107 and the p⁺-type contact regions 108 are formed. Next, an annealing treatment is performed to ion-implanted regions, thereby implementing an activation treatment.

Next, the trenches 116, the gate insulating films 109, the gate electrodes 110, the interlayer insulating film 111, the source electrode 112, a source electrode pad (not depicted), a back electrode (not depicted), and a drain electrode pad (not depicted) are formed. Thus, the SJ-MOSFET 150 depicted in FIG. 14 is completed.

As described, in a portion of the n-type drift layer 102 containing single-crystal 4H-SiC of an n-type, a p-type dopant such as Al ions is periodically implanted at a constant depth, thereby forming the p-type column regions 103 and the n-type column regions 104, whereby the conventional superjunction silicon carbide semiconductor device is fabricated (manufactured).

However, when a SiC epitaxial film is used in which carrier concentration is controlled by doping an n-type dopant in the n-type semiconductor layers (the first n-type drift layer 102a, the second n-type drift layer 102b), a problem arises in that distribution of carrier concentration increases due to an influence of warpage of the substrate during epitaxial growth, temperature distribution, distribution of gas flow, etc.

Embodiments of a superjunction silicon carbide semiconductor device and a method of manufacturing a superjunction silicon carbide semiconductor device according to the present invention is described in detail with reference to the accompanying drawings. In the present description and accompanying drawings, layers and regions prefixed with n or p mean that majority carriers are electrons or holes. Additionally, + or − appended to n or p means that the dopant concentration is higher or lower, respectively, than layers and regions without + or −. Cases where symbols such as n's and p's that include + or − are the same indicate that concentrations are close and therefore, the concentrations are not necessarily equal. A lower-case “n” or “p” is used to denote the conductivity type of a semiconductor. Nitrogen (N) and phosphorus (P) are discussed as dopant elements and elements are indicated by upper-case letters. In the description of the embodiments below and the accompanying drawings, main portions that are identical are given the same reference numerals and are not repeatedly described. Further, with consideration of variation in manufacturing, description indicating the same or equal may be within 5%.

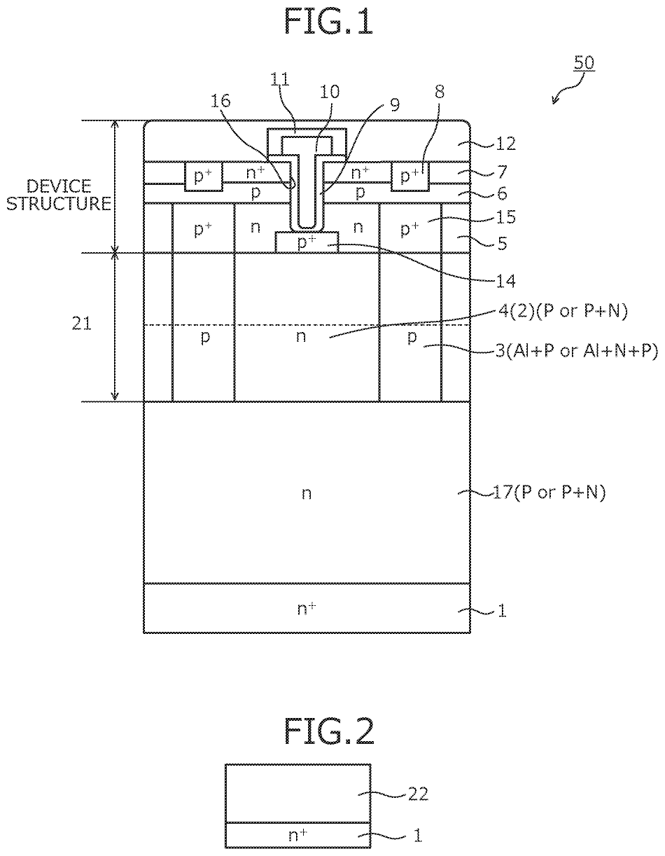

FIG. 1 is a cross-sectional view depicting a structure of a superjunction silicon carbide semiconductor device according to a first embodiment. A superjunction silicon carbide semiconductor device according to the present invention is described taking a SJ-MOSFET 50 as an example. The SJ-MOSFET 50 depicted in FIG. 1 is a SJ-MOSFET having metal oxide semiconductor (MOS) gates in a semiconductor substrate (silicon carbide substrate), at a front surface (surface having a later-described p-type base layer 6) of the semiconductor substrate that contains silicon carbide. In FIG. 1, only two unit cells (functional units of a device) are depicted while other unit cells adjacent thereto are not depicted.

As depicted in FIG. 1, in the SJ-MOSFET 50 according to the first embodiment, an n-type buffer layer (first semiconductor layer of the first conductivity type) 17 is deposited on a first main surface (the front surface), for example, a (0001)-plane (Si-face), of an n⁺-type silicon carbide substrate (silicon carbide semiconductor substrate of a first conductivity type) 1 and a parallel pn structure 21 is provided at the surface of the n-type buffer layer 17.

The n⁺-type silicon carbide substrate 1 is, for example, a single-crystal silicon carbide substrate doped with nitrogen (N). The parallel pn structure 21 has p-type column regions 3 and n-type column regions 4. The n-type column regions 4 conduct electrons, which are majority carriers of the device, and thus may be called an n-type drift layer 2. In the n-type column regions 4, at a surface thereof opposite to that facing the n⁺-type silicon carbide substrate 1, an n-type high-concentration region (second semiconductor layer of the first conductivity type) 5 is provided. The n-type high-concentration region 5 forms a high-concentration n-type drift layer having a doping concentration lower than that of the n⁺-type silicon carbide substrate 1 but higher than that of the n-type column regions 4. The n-type high-concentration region 5 constitutes a so-called current spreading layer (CSL) that reduces carrier spreading resistance.

At a surface of the parallel pn structure 21, opposite to a surface thereof facing the n⁺-type silicon carbide substrate 1, the p-type base layer (third semiconductor layer of a second conductivity type) 6 is provided. Hereinafter, the n⁺-type silicon carbide substrate 1, the n-type buffer layer 17, the parallel pn structure 21, the n-type high-concentration region 5, and the p-type base layer 6 combined are regarded as a silicon carbide semiconductor sheet. A portion above the parallel pn structure 21 constitutes a device structure and in FIG. 1, a trench-type MOSFET device is depicted as an example.

The n-type buffer layer 17 is a layer with a lower doping concentration than the n-type drift layer 2. A high concentration doping layer of another n-type buffer layer (not shown) with an approximately same doping density of the n⁺-type silicon carbide substrate 1 and which promotes electron-hole recombination, thereby suppressing the density of holes injected into the n⁺-type silicon carbide substrate 1 and enabling effective suppression of an occurrence of triangle defects or bar-shaped stacking faults, may be provided between the n-type buffer layer 17 and the n⁺-type silicon carbide substrate 1. The n-type buffer layer 17 is formed by implanting phosphorus (P), which is an n-type, in an epitaxial film 22 (refer to FIG. 2) that is non-doped or doped with an ultralow concentration (about 1×10¹³/cm³ to 10¹⁵/cm³) of nitrogen. Thus, the n-type buffer layer 17 contains phosphorus as a dopant. In the formation of the n-type buffer layer 17, use of implantation of P ions enables improvement of the distribution of carrier concentration as compared to an instance in which formation is by doping of nitrogen with epitaxial growth.

The parallel pn structure 21 is provided in the SJ-MOSFET 50. In the parallel pn structure 21, the n-type column regions (first column regions of the first conductivity type) 4 and the p-type column regions (second column regions of the second conductivity type) 3 are disposed repeatedly alternating with each other in a plane parallel to the front surface of the n⁺-type silicon carbide substrate 1. The n-type column regions 4 are provided so as to reach the n-type high-concentration region 5, from the surface of the n-type buffer layer 17.

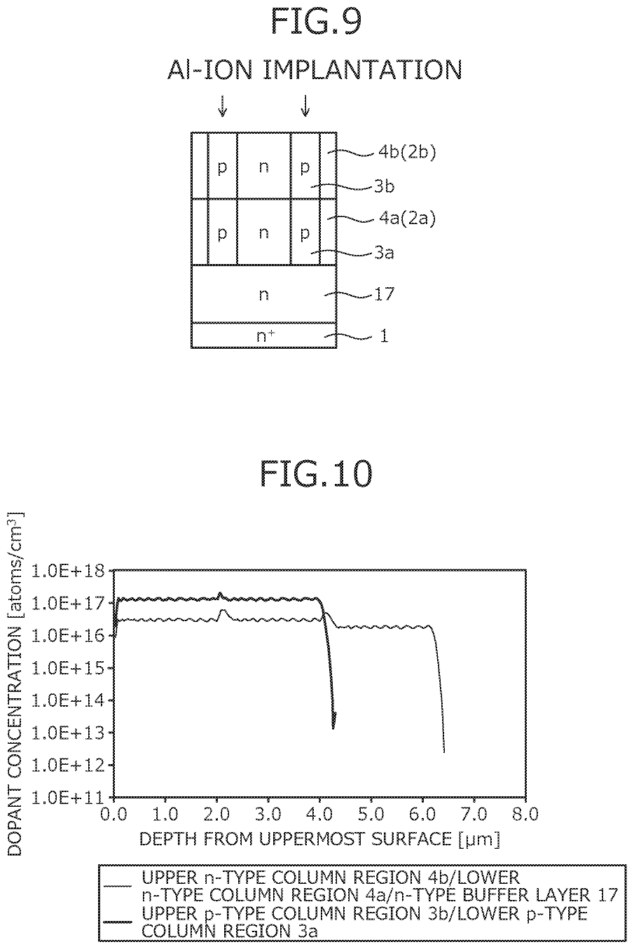

Further, charges of the parallel pn structure 21 are balanced and a product (amount of dopant) obtained by multiplying the width of the p-type column regions 3 by the doping concentration of the p-type column regions 3 is substantially equal to a product (amount of dopant) obtained by multiplying the width of the n-type column regions 4 by the doping concentration of the n-type column regions 4. In particular, said products are within ±5%. Thus, the parallel pn structure 21 is known as a structure that may simultaneously obtain a lower on-resistance and higher breakdown voltage characteristics. In FIG. 1, a dotted line in a center of the parallel pn structure 21 is to indicate that the parallel pn structure 21 is formed by, for example, two layers as described later with reference to FIG. 9. The parallel pn structure 21 may be formed by one layer or may be formed by two or more layers.

As depicted in FIG. 1, at a second surface (back surface, i.e., back surface of the silicon carbide semiconductor sheet) of the n⁺-type silicon carbide substrate 1, a back electrode (not depicted) is provided. The back electrode constitutes a drain electrode. At the surface of the back electrode, the drain electrode pad (not depicted) is provided.

In the silicon carbide semiconductor sheet, at the first main surface thereof (surface having the p-type base layer 6), a trench structure is provided. In particular, from a first surface (surface facing the first main surface of the silicon carbide semiconductor sheet) of the p-type base layer 6, opposite to a second surface thereof facing the n⁺-type silicon carbide substrate 1, trenches 16 penetrate through the p-type base layer 6 and reach the n-type high-concentration region 5. Along inner walls of each of the trenches 16, a gate insulating film 9 is formed at bottoms and sidewalls of the trench 16, and a gate electrode 10 is formed on the gate insulating film 9 in the trench 16. The gate insulating film 9 insulates the gate electrode 10 from the n-type high-concentration region 5 and the p-type base layer 6. A portion of the gate electrode 10 may protrude from a top of the trench 16 toward a later-described source electrode 12.

In the n-type high-concentration region 5, first p⁺-type base regions (second semiconductor regions of the second conductivity type) 14 and second p⁺-type base regions (third semiconductor regions of the second conductivity type) 15 are each selectively provided. Of the bottoms and bottoms corner portions of the trenches 16, the first p⁺-type base regions 14 at least cover the bottoms. The bottom corner portions of the trenches 16 are borders between the bottom and the sidewalls of each of the trenches 16. The second p⁺-type base regions 15 are provided between the trenches 16, at a same depth from surface of the n-type high-concentration region 5 as that of the first p⁺-type base regions 14, said surfaces facing the p-type base layer 6.

At positions closer to the drain electrode than are the bottoms of the trenches 16, pn junctions between the first p⁺-type base regions 14, the second p⁺-type base regions 15, and the n-type column regions 4 are formed. Ends of the first p⁺-type base regions 14 and ends of the second p⁺-type base regions 15 in a depth direction suffice to be positioned so that the pn junctions between the first p⁺-type base regions 14, the second p⁺-type base regions 15, and the n-type column regions 4 are closer to the drain electrode than are the bottoms of the trenches 16 and may be variously changed according to design conditions. Application of high electric field to the gate insulating film 9 at portions along the bottom of each of the trenches 16 may be prevented by the first p⁺-type base regions 14 and the second p⁺-type base regions 15.

In a surface layer of the p-type base layer 6, at the surface thereof facing the source electrode 12, n⁺-type source regions (first semiconductor regions of the first conductivity type) 7 are selectively provided. Further, p⁺-type contact regions 8 may be provided. The n⁺-type source regions 7 are in contact with the trenches 16. Further, the n⁺-type source regions 7 and the p⁺-type contact regions 8 are in contact with each other. In the present specification, regarding “front surface”, the first main surface of the n⁺-type silicon carbide substrate 1 represents, for example, a (0001)-plane (Si-face) and “being provided on the surface of a semiconductor layer” indicates that above the surface of the semiconductor layer, a semiconductor region/semiconductor layer is provided, while “being provided in a surface layer of a semiconductor layer” indicates that in the semiconductor layer, a semiconductor region/semiconductor layer that is exposed at the surface of the semiconductor layer is provided.

The interlayer insulating film 11 is provided in an entire area of the first main surface of the silicon carbide semiconductor sheet so as to cover the gate electrodes 10 embedded in the trenches 16. The source electrode 12 is in contact with the n⁺-type source regions 7 and the p-type base layer 6 via contact holes opened in the interlayer insulating film 11. In an instance in which the p⁺-type contact regions 8 are provided, the source electrode 12 is in contact with the n⁺-type source regions 7 and the p⁺-type contact regions 8. The source electrode 12 is constituted by, for example, a NiSi film. The source electrode 12 is electrically insulated from the gate electrodes 10 by the interlayer insulating film 11. The source electrode pad (not depicted) containing Al or AlSi is provided on the source electrode 12. Between the source electrode 12 and the interlayer insulating film 11, for example, a barrier metal (not depicted) containing Ti and TiN and preventing diffusion of metal atoms from the source electrode 12 to the gate electrodes 10 may be provided.

As described hereinafter, the n-type column regions 4 are formed by ion-implantation of P ions, which are an n-type, in a non-doped epitaxial film 23 (refer to FIG. 4) or doped with an ultralow concentration. Thus, the n-type column regions 4 contain phosphorus as a dopant. This ion implantation is performed in the entire surface and thus, the p-type column regions 3 also contain phosphorus as a dopant. In the formation of the epitaxial film 23, use of implantation of P ions enables improvement of the distribution of carrier concentration as compared to an instance in which formation is by doping of nitrogen with epitaxial growth. Further, a total amount of ion implantation damage to the n-type column regions 4 may be increased.

Further, phosphorus (P) with the atomic mass number 31 has a larger mass than that of nitrogen (N) with the atomic mass number 14 and that of aluminum (Al) with the atomic mass number 27 and by ion-implanting phosphorus, the total amount of ion implantation damage increases, thereby further shortening lifetime. As a result, in a circuit such as that of an inverter, when a body diode of a SiC SJ-MOSFET is used as a free-wheeling diode to reduce the number of components and the module size, an effect of reducing switching loss caused by a reduction in the amount of carriers accumulating in the drift layer and an effect of suppressing conduction degradation caused reduction of electron-hole density of the drift layer are obtained.

Next, a method of manufacturing the superjunction silicon carbide semiconductor device according to the first embodiment is described. FIGS. 2, 3, 4, 5, 6, 7, 8, and 9 are cross-sectional views depicting states of the superjunction silicon carbide semiconductor device according to the first embodiment during manufacture.

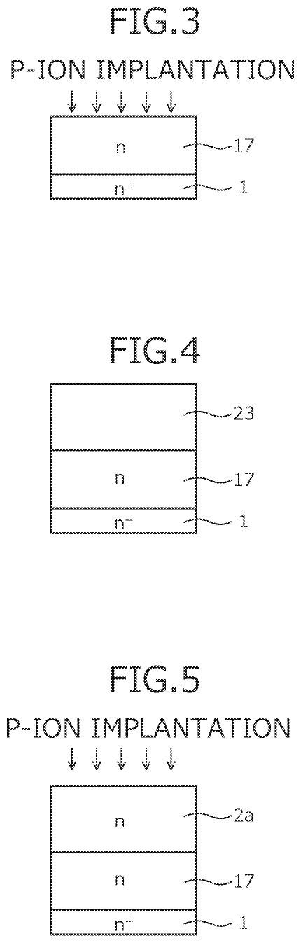

First, the n⁺-type silicon carbide substrate 1 containing single-crystal 4H-SiC of an n-type is prepared. Subsequently, on the first main surface of the n⁺-type silicon carbide substrate 1, the epitaxial film 22 is grown by epitaxy. The epitaxial film 22 may be a non-doped silicon carbide film or a silicon carbide film doped with an ultralow concentration of an n-type dopant, for example, nitrogen atoms in a range of about 1×10¹³ to 10¹⁵/cm³. Further, the epitaxial film 22 may be formed as a non-doped film and thereafter, a desired amount of nitrogen ions may be implanted therein. The state up to here is depicted in FIG. 2. Next, phosphorus ions are implanted from the entire surface of the epitaxial film 22, thereby forming the n-type buffer layer 17. Next, an annealing treatment under an inert gas atmosphere of about 1700 degrees C. is performed, thereby implementing an activation process of the n-type buffer layer 17. The annealing treatment may be performed last, thereby collectively activating ion-implanted regions. The state up to here is depicted in FIG. 3.

Next, on the surface of the n-type buffer layer 17, the epitaxial film 23 is grown by epitaxy. The state up to here is depicted in FIG. 4. Next, phosphorus ions are implanted from the entire surface of the epitaxial film 23, thereby forming a lower n-type drift layer 2a. Here, acceleration energy when the P ions are implanted is set in a range such that a desired reduction of the lifetime is obtained and neither degradation of characteristics nor crystal damage occur. From this perspective, preferably, the acceleration energy when the P ions are implanted may be 700 eV or larger. An upper limit may be set to be not more than 21.5 MeV, preferably, not more than 5.4 MeV, and more preferably, with consideration of throughput of ion-implantation equipment, not more than 3.75 MeV. Further, to improve distribution of the doping concentration in the ion implantation method, utilization of ion implantation equipment further combining use of wafer scanning (mechanical scanning) is preferable to utilization of ion implantation equipment employing only a beam scanning method. Next, an annealing treatment under an inert gas atmosphere of about 1700 degrees C. is performed, thereby implementing an activation process of the lower n-type drift layer 2a. The annealing treatment may be performed last, thereby collectively activating ion-implanted regions. The state up to here is depicted in FIG. 5.

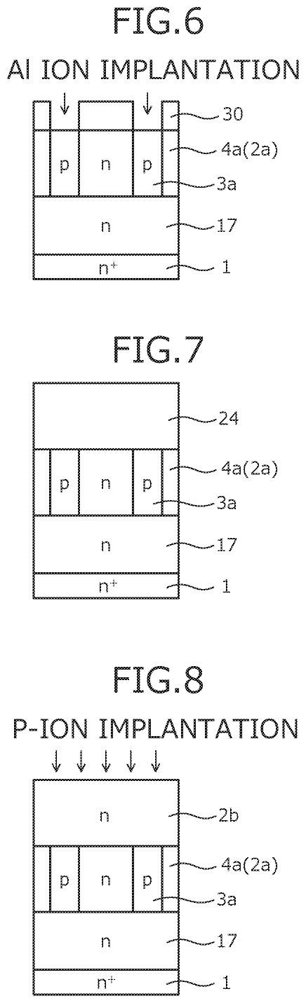

Next, on the surface of the lower n-type drift layer 2a, an ion implantation mask 30 having predetermined openings is formed by photolithography using, for example, an oxide film. Subsequently, aluminum ions are implanted in the openings of the oxide film, thereby forming lower p-type column regions 3a. In the lower n-type drift layer 2a, regions thereof free of the implanted aluminum ions constitute lower n-type column regions 4a. The state up to here is depicted in FIG. 6. Next, the ion implantation mask 30 is removed. Next, an annealing treatment under an inert gas atmosphere of about 1700 degrees C. is performed, thereby implementing an activation process of the lower p-type column regions 3a. The annealing treatment may be performed last, thereby collectively activating ion-implanted regions.

Next, on the surfaces of the lower p-type column regions 3a and the surfaces of the lower n-type column regions 4a, an epitaxial film 24 is grown by epitaxy. The state up to here is depicted in FIG. 7. Next, phosphorus ions are implanted from the entire surface of the epitaxial film 24, thereby forming an upper n-type drift layer 2b. Next, an annealing treatment under an inert gas atmosphere of about 1700 degrees C. is performed, thereby implementing an activation process of the upper n-type drift layer 2b. The annealing treatment may be performed last, thereby collectively activating ion-implanted regions. The state up to here is depicted in FIG. 8.

Next, on the surface of the upper n-type drift layer 2b, an ion implantation mask (not depicted) having predetermined openings is formed by photolithography using, for example, an oxide film. Subsequently, aluminum ions are implanted in the openings of the oxide film, thereby forming the upper p-type column regions 3b. In the upper n-type drift layer 2b, portions thereof free of the implanted aluminum ions constitute upper n-type column regions 4b. Next, the ion implantation mask is removed. Next, an annealing treatment under an inert gas atmosphere of about 1700 degrees C. is performed, thereby implementing an activation process of the upper p-type column regions 3b. The annealing treatment may be performed last, thereby collectively activating ion-implanted regions. Next, the ion implantation mask is removed. The state up to here is depicted in FIG. 9.

The lower p-type column regions 3a and the upper p-type column regions 3b constitute the p-type column regions 3 while the lower n-type column regions 4a and the upper n-type column regions 4b constitute the n-type column regions 4 and thus, the parallel pn structure 21 is formed. Here, while an example in which the parallel pn structure 21 is formed by two stacked layers (the epitaxial films 23, 24), the parallel pn structure 21 may be formed by three or more stacked layers. The description above describes manufacturing processes depicted in FIGS. 2 to 9 and up to here, the n⁺-type silicon carbide substrate 1, the n-type buffer layer 17, and the parallel pn structure 21 depicted in FIG. 1 are formed.

Here, FIG. 10 is a graph showing concentrations of P and Al (calculated based on results of simulation) in regions implanted with P ions and Al ions in the structure depicted in FIG. 9, in the method of manufacturing the superjunction silicon carbide semiconductor device according to the first embodiment. In FIG. 10, a vertical axis indicates concentrations of P and Al in units of atoms/cm³. Notations on the vertical axis, for example, “1.0E+18” means 1.0×10¹⁸. A horizontal axis indicates depth from the surface of the epitaxial film 24 in units of μm. In FIG. 10, a thin line indicates the concentration of P in the upper n-type column regions 4b, the lower n-type column regions 4a, and the n-type buffer layer 17, sequentially from an origin (0 μm). A thick line indicates the concentration of Al in the upper p-type column regions 3b and the lower p-type column regions 3a, sequentially from the origin. The epitaxial films 23, 24 are assumed to have a thickness of 2 μm.

The n-type buffer layer 17 is assumed to be formed by performing implantation of P ions so that, after the epitaxial film 22 is deposited without doping, the concentration of implanted P ions of a box profile portion (portion in which the concentration of P ions or Al ions is constant) becomes an average of about 1.8×10¹⁶ atoms/cm³.

Further, the lower n-type drift layer 2a is assumed to be formed by performing implantation of P ions so that, after the epitaxial film 23 is deposited without doping, the concentration of implanted P ions of the box profile portion becomes an average of about 3.0×10¹⁶ atoms/cm³.

Further, the lower p-type column regions 3a are assumed to be formed by forming an ion implantation mask having predetermined openings by photolithography using an oxide film and performing implantation of Al ions in the openings of the oxide film so that the concentration of implanted Al ions of the box profile portion becomes about 1.3×10¹⁷ atoms/cm³.

Further, the upper n-type drift layer 2b is assumed to be formed by depositing the epitaxial film 24 without doping after the oxide film is removed and performing implantation of P ions so that the concentration of implanted P ions of the box profile portion becomes about 3.0×10¹⁶ atoms/cm³.

Further, the upper p-type column regions 3b is assumed to be formed by forming an ion implantation mask having predetermined openings by photolithography using an oxide film and performing implantation of Al ions in the openings of the oxide film so that the concentration of the implanted Al ions in the box profile portion becomes about 1.3×10¹⁷ atoms/cm³. Portions connecting layers and regions are overlapping ion-implanted regions, resulting in increased concentrations and thus, exhibit peaks in concentration.

Here, description of the method of manufacturing the semiconductor device depicted in FIG. 1 is continued. The following manufacturing procedures are well known and thus, not depicted in the drawings. After the process depicted in FIG. 9, on the surfaces of the p-type column regions 3 and on the surfaces of the n-type column regions 4, the n-type high-concentration region 5 doped with nitrogen is formed by epitaxial growth. Next, in the n-type high-concentration region 5, the first p⁺-type base regions 14 and the second p⁺-type base regions 15 are formed by selective ion implantation using a selective mask.

Next, on the surface of the n-type high-concentration region 5, the p-type base layer 6 doped with a p-type dopant such as aluminum is formed by epitaxial growth. Next, on the surface of the p-type base layer 6, an implantation mask having predetermined openings is formed by photolithography using, for example, an oxide film, a semiconductor film, or a stacked structure of an oxide film and a semiconductor film. An n-type dopant such as phosphorus (P) is ion-implanted in the openings, thereby forming the n⁺-type source regions 7 in portions of the p-type base layer 6, at the surface of the p-type base layer 6. Next, the ion implantation mask used in forming the n⁺-type source regions 7 is removed and the p⁺-type contact regions 8 may be formed by a same method in which, an ion implantation mask having predetermined openings is formed and a p-type dopant such as aluminum is ion-implanted in portions of the p-type base layer 6. The doping concentration of the p⁺-type contact regions 8 is set so as to be higher than the doping concentration of the p-type base layer 6.

Next, an annealing treatment under an inert gas atmosphere of about 1700 degrees C. is performed, thereby implementing an activation process of the n-type column regions 4, the n⁺-type source regions 7, and the p⁺-type contact regions 8, etc. As described above, the ion-implanted regions may be activated collectively by a single session of the annealing treatment, or the ion-implanted regions may be activated by performing the annealing treatment each time ion implantation is performed.

Next, on the surface of the p-type base layer 6, a trench formation mask having predetermined openings is formed by photolithography using, for example, an oxide film. Next, the trenches 16 penetrating through the p-type base layer 6 and reaching the n-type high-concentration region 5 are formed by dry etching. The bottoms of the trenches 16 may reach the first p⁺-type base regions 14 formed in the n-type high-concentration region 5. Next, the trench formation mask is removed.

Next, along the surfaces of the n⁺-type source regions 7 and the bottoms and the sidewalls of the trenches 16, the gate insulating film 9 is formed. The gate insulating film 9 may be formed by thermal oxidation at a temperature of about 1000 degrees C. under an oxygen atmosphere. Further, the gate insulating film 9 may be formed by a deposition method by a chemical reaction such as that for a high temperature oxide (HTO) or the like.

Next, on the gate insulating film 9, for example, a polycrystalline silicon layer doped with phosphorus may be deposited by a chemical vapor deposition reaction. The polycrystalline silicon layer may be formed so as to be embedded in the trenches 16. The polycrystalline silicon layer is patterned by photolithography, thereby leaving portions thereof in the trenches 16, whereby the gate electrodes 10 are formed.

Next, for example, a phosphate glass having a thickness of about 1 μm is deposited so as to cover the gate insulating film 9 and the gate electrodes 10, thereby forming the interlayer insulating film 11. Next, the barrier metal (not depicted) containing titanium (Ti) or titanium nitride (TiN) may be formed so as to cover the interlayer insulating film 11. The interlayer insulating film 11 and the gate insulating film 9 are patterned by photolithography, forming contact holes exposing the n⁺-type source regions 7. In an instance in which the p⁺-type contact regions 8 are formed, the contact holes are formed exposing the n⁺-type source regions 7 and the p⁺-type contact regions 8. Thereafter, a heat treatment (reflow) is performed, planarizing the interlayer insulating film 11.

Next, in the contact holes and on the interlayer insulating film 11, a conductive film constituting the source electrode 12 is provided. The conductive film is selectively removed and left only in the contact holes as the source electrode 12, whereby the n⁺-type source regions 7 and the source electrode 12 are connected to each other. In an instance in which the p⁺-type contact regions 8 are formed, the n⁺-type source regions 7 and the p⁺-type contact regions 8 are connected to the source electrode 12. Next, the source electrode 12 excluding portions thereof in the contact holes is selectively removed.

Next, for example, an electrode pad constituting the source electrode pad (not depicted) is formed by sputtering on the source electrode 12 at the front surface of the silicon carbide semiconductor sheet and at an upper portion of the interlayer insulating film 11.

Next, on the second surface of the n⁺-type silicon carbide semiconductor substrate 1, the back electrode containing nickel or the like is provided. Thereafter, an annealing treatment under an inert gas atmosphere of about 1000 degrees C. is performed, thereby forming the back electrode in ohmic contact with the n⁺-type silicon carbide semiconductor substrate 1. In an instance in which the trenches 16 are omitted, n-type well regions are formed in portions of surface regions of the p-type base layer 6, the front side of the silicon carbide semiconductor sheet is thermally oxidized, the gate insulating film 9 is formed, the p-type base layer 6 and the regions formed at the surface of the p-type base layer 6 are covered by the gate insulating film 9, the polycrystalline silicon layer is formed on the gate insulating film 9 as the gate electrode 10, the polycrystalline silicon layer is patterned and selectively removed, leaving portions thereof on portions of the p-type base layer 6 intervening between the n⁺-type source regions 7 and the n-type well regions, and the interlayer insulating film 11 is formed so as to cover the gate electrode 10. Thus, the silicon carbide semiconductor device depicted in FIG. 1 is completed.

As described, according to the superjunction silicon carbide semiconductor device and the method of manufacturing the superjunction silicon carbide semiconductor device according to the first embodiment, when the n-type semiconductor layer is formed, distribution of carrier concentration may be improved by using implantation of P ions as compared to an instance of formation by epitaxial growth. Further, the total amount of ion implantation damage to the n-type column regions may be increased. Further, P ions having a larger mass than that of N ions and that of Al ions are implanted, whereby the total ion implantation damage is increased and the lifetime is further shortened. As a result, in a circuit such as that of an inverter, when a body diode of a SiC SJ-MOSFET is used as a free-wheeling diode to reduce the number of components and the module size, an effect of reducing switching loss caused by a reduction in the amount of carriers accumulating in the drift layer and an effect of suppressing conduction degradation caused by a reduction of electron-hole density of the drift layer are obtained.

Next, a second embodiment is described. In the second embodiment, the parallel pn structure 21 depicted in FIG. 1 is modified to a parallel pn structure 21′. The first embodiment assumes an instance in which the thickness of one layer of the epitaxial film 23 forming the parallel pn structure 21 is, for example, about 2 μm and as depicted in FIG. 10, implantation of P ions of the n-type column regions is possible throughout the thickness of the epitaxial film 23. In contrast, in the second embodiment, a thick layer in which the thickness of the one layer of the epitaxial film 23 is assumed to exceed, for example, about 2.5 μm; and a device structure in a case in which implantation of P ions throughout the thickness is difficult and a method of manufacturing of the device structure are provided. As described hereinafter, in the thick epitaxial film, the n-type column regions are configured by a two-tier structure in which shallow portions are formed by implantation of P ions and deep portions are formed by implantation of N ions.

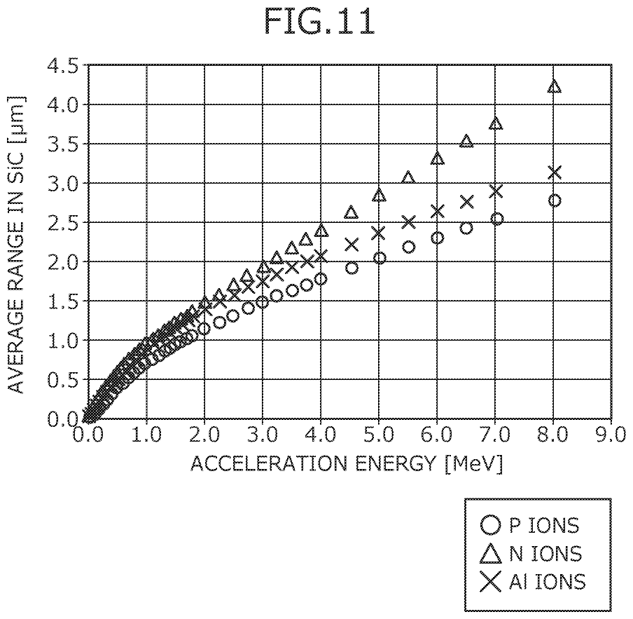

FIG. 11 is a graph showing results of simulation of the average range with respect to acceleration energies of N ions, Al ions, and P ions implanted in SiC. The average ranges were obtained assuming density of SiC to be 3.21 g/cm³. Further, the crystal structure of SiC was not considered. In FIG. 11, a vertical axis indicates average ranges of N ions, Al ions, and P ions in SiC, in units of μm, while a horizontal axis indicates acceleration energies of N ions, Al ions, and P ions, in units of MeV. As depicted in FIG. 11, the P ions have the largest mass and thus, for the same acceleration energy, the implantation depth is shallowest. Further, the N ions have the least mass and thus, for the same acceleration energy, the implantation depth is deepest. In other words, the P ions are difficult to implant deeper in a layer than are N ions and the second embodiment provides a method of solving this problem.

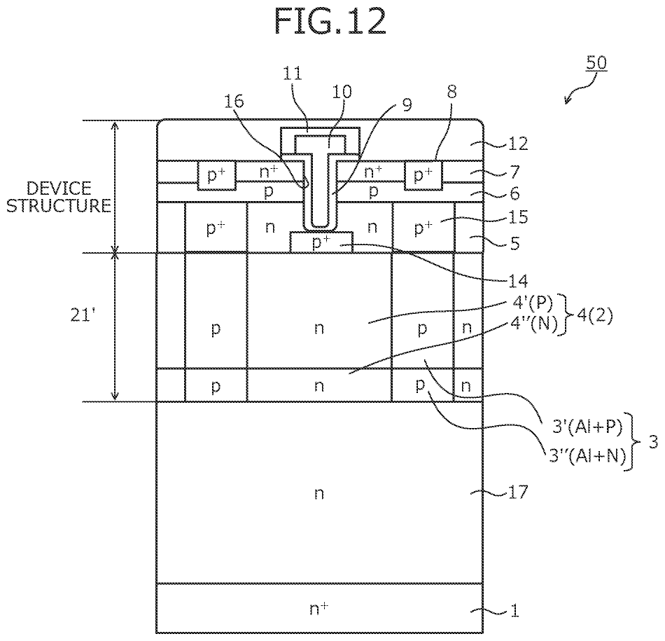

FIG. 12 is a cross-sectional view depicting a structure of the superjunction silicon carbide semiconductor device according to the second embodiment. In the superjunction silicon carbide semiconductor device according to the second embodiment, the parallel pn structure 21′ is, for example, a single epitaxial layer and the n-type column regions 4 are configured by first n-type column regions 4′ implanted with P ions and second n-type column regions 4″ implanted with N ions. Thus, the p-type column regions 3 are also configured by first p-type column regions 3′ implanted with Al ions and P ions and second p-type column regions 3″ implanted with Al ions and N ions.

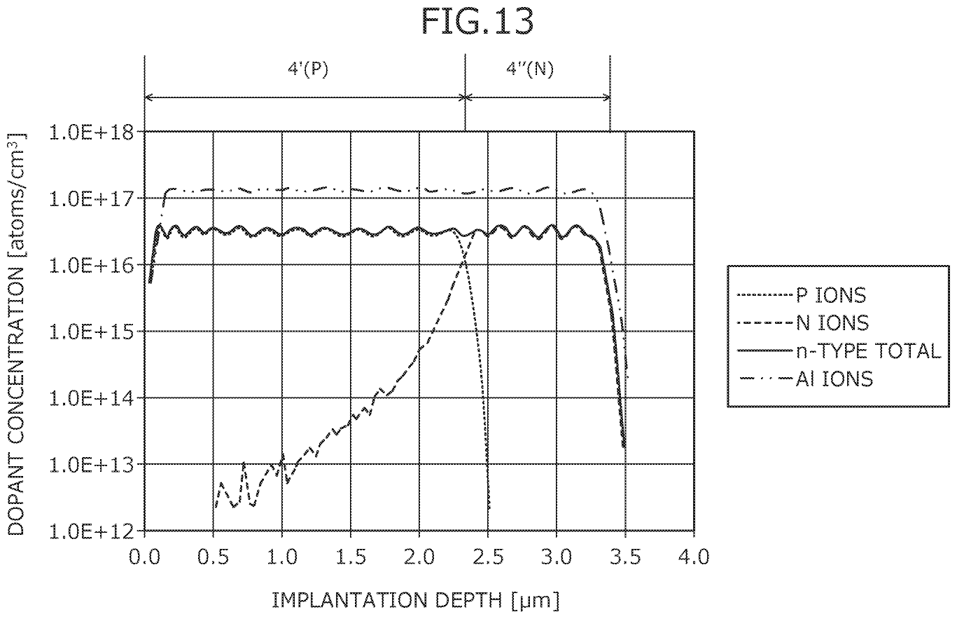

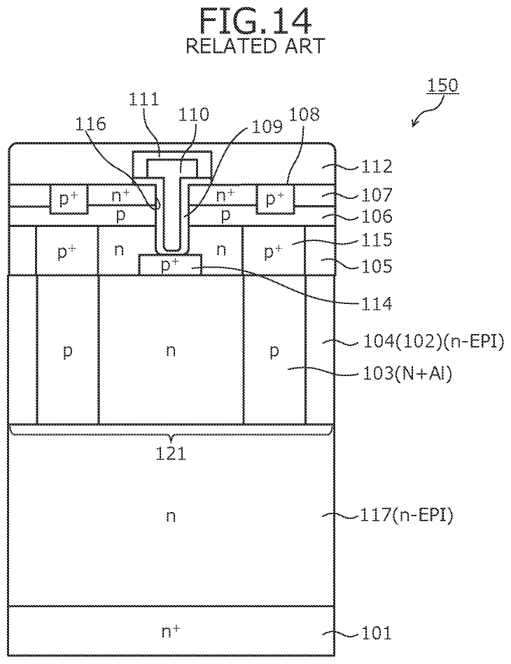

FIG. 13 shows results of simulation of profiles of dopant concentrations of the parallel pn structure 21′ depicted in FIG. 12. Regarding acceleration energy, ion implantation equipment capable of accelerating Al ions up to only 8000 keV, P ions up to only 5400 keV, and N ions up to only 6300 keV is assumed to be used. The p-type column regions 3 have a target ion implantation profile in which the target concentration of 1.3×10¹⁷ atoms/cm³ of Al ions is implanted in 16 stages acceleration energy, from 120 keV to 8000 keV. In contrast, the n-type column regions 4 have a target ion implantation profile with an average concentration of 3.0×10¹⁶ atoms/cm³ for an instance in which after N ions are implanted in 6 stages acceleration energy, from 3920 keV to 5780 keV, so as to have a box profile, P ions are implanted in 12 stages acceleration energy, from 85 keV to 5400 keV, so as to have a box profile. As depicted in FIG. 13, in the n-type column regions 4, while an overlapping region in which both P ions and N ions are implanted occurs, such a region is omitted from (not depicted in) the graph in FIG. 12. To improve the distribution of the doping concentration in the ion implantation method, utilization of ion implantation equipment further combining use of wafer scanning (mechanical scanning) is preferable to utilization of ion implantation equipment employing only a beam scanning method.

With such a structure, even for regions in which P ions cannot penetrate deeply due to the capability of the ion implantation equipment, N ions having a lower mass and a longer average range than that of P ions are also used, whereby the n-type column regions 4 may be formed to be longer. As a result, depths for each layer of the n-type column regions 4 and the p-type column regions 3 may be increased as compared to the depths in the first embodiment.

Next, a method of manufacturing the superjunction silicon carbide semiconductor device according to the second embodiment is described. In the fabrication processes below, the first and second n-type column regions 4′, 4″ are first formed as a layered structure and next, in the layered structure, the p-type column regions are selectively ion-implanted, whereby remaining portions are established as the n-type column regions. In the description of the method of manufacturing below, the first and second n-type column regions 4′, 4″ are assumed to mean any of the n-type column regions established in the first layered structure or thereafter, depending on the stage of the fabrication processes.

First, similar to the method of manufacturing the superjunction silicon carbide semiconductor device according to the first embodiment, the n-type buffer layer 17 is formed and on the surface of the n-type buffer layer 17, the epitaxial film 23 is grown by epitaxy. The processes up to here are identical to the processes depicted in FIGS. 2 and 3. Next, in FIG. 5, while P ions are implanted in the epitaxial film 23 overall, in the second embodiment, nitrogen ions are implanted at deep positions (regions in contact with the n-type buffer layer 17) from the surface of the epitaxial film 23, thereby forming the second n-type column regions 4″.

Next, P ions are implanted from the surface of the epitaxial film 23, thereby forming the first n-type column regions 4′ at shallow positions from the surface of the epitaxial film 23. Next, an annealing treatment under an inert gas atmosphere of about 1700 degrees C. is performed, thereby implementing an activation process of the first n-type column regions 4′ and the second n-type column regions 4″. The annealing treatment may be performed last, thereby collectively activating ion-implanted regions. Further, the carrier concentration of the second n-type column regions 4″ may be the same or may be different from the carrier concentration of the first n-type column regions 4′ formed by implantation of phosphorus ions.

Next, on the surfaces of the first n-type column regions 4′, the ion implantation mask 30 having predetermined openings is formed by photolithography using, for example, an oxide film. Subsequently, aluminum ions are implanted in the openings of the oxide film, thereby forming the p-type column regions 3. Regions free of implanted aluminum ions constitute the n-type column regions 4. Al is additionally implanted in the n-type column regions 4 and thus, the p-type column regions 3 are formed having a structure including the first p-type column regions 3′ and the second p-type column regions 3″. Next, the ion implantation mask 30 is removed. Next, an annealing treatment under an inert gas atmosphere of about 1700 degrees C. is performed, thereby implementing an activation process of the p-type column regions 3. The annealing treatment may be performed last, thereby collectively activating ion-implanted regions. As described, the parallel pn structure 21′ of the second embodiment is formed. Here, the epitaxial film 23 is assumed to have a single layer and while an example of forming the parallel pn structure 21′ is not depicted, the epitaxial film 23 may be formed by two or more stacked layers. Subsequently, similar to the method of manufacturing the superjunction silicon carbide semiconductor device according to the first embodiment, the process of forming the n-type high-concentration region 5 is performed, whereby the silicon carbide semiconductor device depicted in FIG. 12 is completed.

As described above, according to the superjunction silicon carbide semiconductor device and the method of manufacturing the superjunction silicon carbide semiconductor device according to the second embodiment, implantation of P ions is used when the n-type semiconductor layer is formed, whereby effects similar to those of the first embodiment are obtained. Furthermore, even for regions in which P ions cannot penetrate deeply, implantation of N ions is used and thus, the n-type column regions may be formed and the depths of the n-type column regions and of the p-type column regions may be deeper than those in the first embodiment. For the n-type buffer layer as well, when regions in which P ions cannot penetrate deeply are present, implantation of N ions may also be used similarly as for deep regions.

In the foregoing, in the present invention, while an instance in which a main surface of the silicon carbide substrate containing silicon carbide is assumed to be a (0001)-plane and on the (0001)-plane, a MOS is configured is described as an example, without limitation hereto, various modifications such as in the wide band gap semiconductor, orientation of the substrate surface, and the like are possible. Further, in the embodiments of the present invention, while a trench-type MOSFET is described as an example, without limitation hereto, application to semiconductor devices of various configurations such as MOS-type semiconductor devices, like IGBTs and planar type MOSFETs, etc. is possible.

According to the invention described above, when the n-type semiconductor layer is formed, implantation of P ions is used, whereby in-plane distribution of carrier concentration may be improved as compared to an instance of formation by epitaxial growth. Further, the amount of ion implantation damage to the n-type column regions may be increased. Further, P ions having a larger mass than that of N ions and that of Al ions are implanted, whereby the total amount of ion implantation damage increases and the lifetime is further shortened. As a result, in a circuit such as that of an inverter, when a body diode of a SiC SJ-MOSFET is used as a free-wheeling diode to reduce the number of components and the module size, an effect of reducing switching loss caused by a reduction in the amount of carriers accumulating in the drift layer and an effect of suppressing conduction degradation caused by a reduction of electron-hole density of the drift layer are obtained.

The superjunction silicon carbide semiconductor device according to the present invention and the method of manufacturing the superjunction silicon carbide semiconductor device achieve an effect in that when an n-type semiconductor layer is formed, the effect of in-plane distribution of carrier concentration may be reduced.

As described, the superjunction silicon carbide semiconductor device according to the present invention and the method of manufacturing the superjunction silicon carbide semiconductor device are useful for high-voltage semiconductor devices used in power converting equipment, power source devices of various types of industrial machines, etc.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A superjunction silicon carbide semiconductor device, comprising:
a silicon carbide semiconductor substrate of a first conductivity type, the silicon carbide semiconductor substrate having a main surface;
a first semiconductor layer of the first conductivity type, provided at the main surface of the silicon carbide semiconductor substrate, the first semiconductor layer having a first surface and a second surface opposite to each other, the second surface of first semiconductor layer facing the silicon carbide semiconductor substrate;
a parallel pn region provided at the first surface of the first semiconductor layer, the parallel pn region having a first surface and a second surface opposite to each other, the second surface of the parallel pn region facing the silicon carbide semiconductor substrate, the parallel pn region having therein a plurality of first column regions of the first conductivity type and a plurality of second column regions of a second conductivity type disposed repeatedly alternating with one another in a direction parallel to the main surface;
a second semiconductor layer of the first conductivity type, provided at the first surface of the parallel pn region, the second semiconductor layer having a first surface and a second surface opposite to each other, the second surface of the second semiconductor layer facing the silicon carbide semiconductor substrate;
a third semiconductor layer of the second conductivity type, provided at the first surface of the second semiconductor layer;
a first semiconductor region of the first conductivity type, selectively provided in the third semiconductor layer and having a doping concentration higher than a doping concentration of the first semiconductor layer;
a trench penetrating through the first semiconductor region and the third semiconductor layer and reaching the second semiconductor layer;
a second semiconductor region of the second conductivity type, provided in the second semiconductor layer and in contact with a bottom of the trench;
a third semiconductor region of the second conductivity type, provided in the second semiconductor layer, at the first surface of the second semiconductor layer, apart from the trench;
a gate insulating film provided in the trench;
a gate electrode provided on the gate insulating film, in the trench; and
an electrode in contact with the first semiconductor region and the third semiconductor layer, wherein
the plurality of first column regions and the plurality of second column regions contain phosphorus as a dopant thereof.

2. The superjunction silicon carbide semiconductor device according to claim 1, wherein
the plurality of first column regions includes:
a plurality of lower first column regions facing silicon carbide semiconductor substrate, and
a plurality of upper first column regions facing the second semiconductor layer;
the plurality of lower first column regions contain nitrogen as a dopant thereof,
the plurality of upper first column regions and the plurality of second column regions contain phosphorus as the dopant thereof.

3. The superjunction silicon carbide semiconductor device according to claim 1, wherein the first semiconductor layer contains phosphorus as a dopant thereof.

4. A method of manufacturing a superjunction silicon carbide semiconductor device, the method comprising:
preparing a silicon carbide semiconductor substrate of a first conductivity type, the silicon carbide semiconductor substrate having a main surface;
forming a first semiconductor layer of the first conductivity type, at the main surface of the silicon carbide semiconductor substrate, the first semiconductor layer having a first surface and a second surface opposite to each other, the second surface facing the silicon carbide semiconductor substrate;
forming a parallel pn region at the first surface of the first semiconductor layer, the parallel pn region having a first surface and a second surface opposite to each other, the second surface facing the silicon carbide semiconductor substrate, the parallel pn region having therein a plurality of first column regions of the first conductivity type and a plurality of second column regions of a second conductivity type disposed repeatedly alternating with one another in a direction parallel to the main surface;
forming a second semiconductor layer of the first conductivity type, at the first surface of the parallel pn region, the second semiconductor layer having a first surface and a second surface opposite to each other, the second surface facing the silicon carbide semiconductor substrate;
forming a third semiconductor layer of the second conductivity type, at the first surface of the second semiconductor layer;
selectively forming a first semiconductor region of the first conductivity type, in the third semiconductor layer, the first semiconductor region having a doping concentration higher than a doping concentration of the first semiconductor layer;
forming a second semiconductor region of the second conductivity type, in the second semiconductor layer;
forming a third semiconductor region of the second conductivity type, in the second semiconductor layer at the first surface thereof;
forming a trench penetrating through the first semiconductor region and the third semiconductor layer, and reaching the second semiconductor layer, the trench having a bottom in contact with the second semiconductor region;
forming a gate insulating film in the trench;
forming a gate electrode on the gate insulating film, in the trench; and
forming an electrode in contact with the first semiconductor region and the third semiconductor layer, wherein
forming the parallel pn region includes a process of:
forming, at the first surface of the first semiconductor layer, an epitaxial film containing silicon carbide, and
implanting phosphorus ions therein, from an entire surface of the epitaxial film, thereby forming a semiconductor region of the first conductivity type, and
in the semiconductor region, implanting dopant ions of the second conductivity type so as to selectively form a semiconductor region of the second conductivity type,
the process being performed multiple times.

5. The method according to claim 4, wherein the process further includes, before implanting the phosphorus ions, implanting, in a lower region of the epitaxial film, nitrogen ions from the entire surface of the epitaxial film, the lower region facing the silicon carbide semiconductor substrate.

6. The method according to claim 4, wherein forming the first semiconductor layer includes forming the epitaxial film at the main surface of the silicon carbide semiconductor substrate and implanting only the phosphorus ions therein from the entire surface of the epitaxial film.

7. The method according to claim 4, wherein the epitaxial film is a non-doped epitaxial film of the silicon carbide, or an epitaxial film of silicon carbide with an ultralow concentration of nitrogen atoms in a range of 1×10¹³ to 10¹⁵/cm³.

8. The method according to claim 4, wherein the first semiconductor layer contains phosphorus and nitrogen as the dopant.
